(19) United States
(12) Patent Application Publication
(10) Pub. No.: US 2009/0167169 A1
(43) Pub. Date: Jul. 2, 2009

(54) ORGANIC LIGHT EMITTING DIODE AND METHOD FOR MANUFACTURING THE SAME

(75) Inventors: Hyung Sup LEE, Gyeonggi-Do (KR); Chul Hwan KIM, Gyeonggi-do (KR); Suk Ju PARK, Gyeonggi-Do (KR)

Correspondence Address: HOSOON LEE, 9600 SW OAK ST. SUITE 525, TIGARD, OR, 97223, US

(73) Assignees: JUSUNG ENGINEERING CO., LTD, Gyeonggi-do (KR); ADS, Gyeonggi-do (KR)

(21) Appl. No.: 12/340,666

(22) Filed: Dec. 20, 2008

(30) Foreign Application Priority Data
Dec. 27, 2007 (KR) 10-2007-0138220

(51) Int. Cl. H01J 1/62; H01L 21/02

(52) U.S. Cl. 313/504; 438/99; 257/E21.002

(57) ABSTRACT

Provided are an organic light emitting diode (OLED) and a method for manufacturing the same. The method for manufacturing the OLED includes forming a first electrode on a substrate using a metal paste, forming an organic thin film on the first electrode, and depositing a second electrode on the organic thin film. Herein, the second electrode includes a transparent conductive oxide.

### CROSS-REFERENCE TO RELATED APPLICATION

This application claims priority to Korean Patent Application No. 10-2007-0138220 filed on Dec. 27, 2007 and all the benefits accruing therefrom under 35 U.S.C. §119, the contents of which are incorporated by reference in their entirely.

### BACKGROUND

The present disclosure relates to an organic light emitting diode (OLED) and a method for manufacturing the same, and more particularly, to a top emission OLED in which an electrode is formed using a metal paste, and a method for manufacturing the same.

An OLED, which is considered as a promising next-generation flat panel display to replace a liquid crystal display (LCD) and a plasma display panel (PDP). Generally, the OLED includes multi-layered organic compounds of illuminants, and emits light as current flows when a voltage is applied thereto.

While an LCD displays an image by selectively transmitting light and a PDP displays an image through plasma discharge, an OLED displays an image through electroluminescent mechanism. That is, an OLED includes two electrodes, i.e., cathode and anode, and an organic emission layer interposed therebetween, and emits light in such a way that holes and electrons are injected into the organic luminescent layer from the anode and cathode, respectively, and then recombined with each other to create a recombination energy stimulating organic molecules. Such an OLED is being popularly applied to small-sized displays because it is self-luminescent and also has several advantageous merits such as wide viewing angle, high-definition, high image quality and high response time.

FIG. 1 is a schematic sectional view of a related art OLED. Referring to FIG. 1, the related art OLED includes a substrate 10, an anode 20, an organic thin film 30, and a cathode 40. To be specific, the related art OLED has a stacked structure where the anode 20, tie organic thin film 30 and the cathode 40 are formed on the substrate 10 in sequence.

A glass substrate is generally used for the substrate 10, and a plastic substrate may also be used in case of realizing a flexible display. The anode 20 may be formed of a transparent conductive material such as indium till oxide (ITO) and indium zinc oxide (IZO), and patterns are formed using lithography.

The organic thin film 30 and the cathode 40 are sequentially formed on the anode 20, and tile cathode 40 is formed of aluminum (Al), silver-magnesium (Ag—Mg) alloy, or the like, using evaporation, sputtering, or E-beam.

In the related art, however, a process of forming an anode using lithography is too complicated, requires high installation cost of equipment and high maintenance cost, and produces contaminants periodically. Furthermore, a patterned anode is apt to have non-uniform resistance and low reliability due to the deformation of an edge of the patterned anode. Therefore, to improve the resistance and reliability, it should be necessary to additionally perform a process of forming an insulator on the edge of the patterned anode.

Moreover, the evaporation and E-beam are not suitable for a large-sized screen, and the sputtering may cause an organic thin film to be damaged.

### SUMMARY

The present disclosure provides a top emission organic light emitting diode and a method for manufacturing the same, which can simplify a manufacturing process, minimize the discharge amount of contaminants, and reduce manufacturing cost by forming a metal electrode using a metal paste.

In accordance with an exemplary embodiment, a method for manufacturing an organic light emitting diode (OLED) includes: forming a first electrode on a substrate using a metal paste; forming an organic thin film on the first electrode; and depositing a second electrode on the organic thin film, the second electrode including a transparent conductive oxide.

The forming of the first electrode may include: coating the substrate with a metal paste; drying the metal paste; and performing a heat-treatment of the metal paste.

The organic thin film may include an organic emission layer.

The method may further include depositing an inorganic thin film on the first electrode after the forming of the first electrode on the substrate, wherein the inorganic thin film is an N-type inorganic thin film formed by adding an N-type impurity into an inorganic compound.

The method may further include forming an encapsulation layer.

The metal paste may include one of silver (Ag), aluminum (Al) and silver-magnesium (Ag—Mg) alloy.

The performing of the heat-treatment of the metal paste may include performing the heat-treatment at a temperature ranging from approximately 100° C. to approximately 500° C.

The coating of the substrate with the metal paste may include coating the substrate with the metal paste under atmospheric pressure using one of a screen printing method, a spin-coating method, a gravier printing method, and an inkjet printing method.

The organic thin film may further include one of an electron injection layer, an electron transport layer, a hole transport layer, a hole injection layer, and combinations thereof.

In accordance with another exemplary embodiment, an OLED includes: a first electrode disposed on a substrate; an organic thin film disposed on the first electrode; and a second electrode disposed on the organic thin film, and formed of a transparent conductive oxide, wherein the first electrode is formed using a metal paste.

The organic thin film may include an organic emission layer.

The OLED may further include an inorganic thin film disposed between the first electrode and the organic thin film, wherein the inorganic thin film is an N-type inorganic thin film formed by adding an N-type impurity into an inorganic compound.

The OLED may further include an encapsulation layer provided on the second electrode.

The metal paste may include one of silver (Ag), aluminum (Al) and silver-magnesium (Ag—Mg) alloy.

The transparent conductive oxide may include one of indium tin oxide (ITO), indium zinc oxide (IZO), and Al-doped zinc oxide (AZO).

The organic thin film may further include one of an electron injection layer, an electron transport layer, a hole transport layer, a hole injection layer, and combinations thereof.

### BRIEF DESCRIPTION OF THE DRAWINGS

Exemplary embodiments can be understood in more detail from the following description taken in conjunction with the accompanying drawings, in which:

FIG. 1 is a schematic sectional view of a related art organic light emitting diode (OLED);

FIG. 2 is a schematic sectional view of an OLED in accordance with an exemplary embodiment;

FIG. 3 is a schematic sectional view of an OLED in accordance with another exemplary embodiment;

FIG. 4 is a schematic sectional view of an OLED in accordance with still another exemplary embodiment;

FIG. 5 is a schematic sectional view of an OLED in accordance with yet another exemplary embodiment;

FIG. 6 is a schematic sectional view of an OLED in accordance with further exemplary embodiment;

FIG. 7 is a flowchart illustrating a method for manufacturing an OLED in accordance with an exemplary embodiment;

FIGS. 8A through 8F are sectional views illustrating the method for manufacturing the OLED in FIG. 7; and

FIG. 9 is a flowchart illustrating a method for manufacturing an OLED in accordance with another exemplary embodiment.

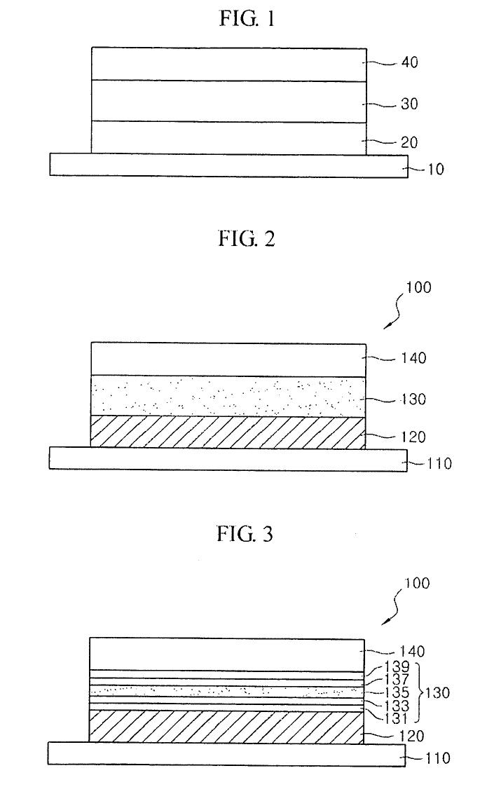

### DETAILED DESCRIPTION OF EMBODIMENTS

In the figures, the dimensions of layers and regions are exaggerated for clarity of illustration. Like reference numerals refer to like elements throughout. It will also be understood that when a layer, a film, a region or a plate is referred to as being ‘on’ another one, it can be directly on the other one, or one or more intervening layers, films, regions or plates may also be present. Further, it will be understood that when a layer, a film, a region or a plate is referred to as being ‘under’ another one, it can be directly under the other one, and one or more intervening layers, films, regions or plates may also be present. In addition, it will also be understood that when a layer, a film, a region or a plate is referred to as being ‘between’ two layers, films, regions or plates, it can be the only layer, film, region or plate between the two layers, films, regions or plates, or one or more intervening layers, films, regions or plates may also be present.

Hereinafter, specific embodiments will be described in detail with reference to the accompanying drawings.

FIG. 2 is a schematic sectional view of an OLED in accordance with an exemplary embodiment, and FIG. 3 is a schematic sectional view of an OLED in accordance with another exemplary embodiment.

Referring to FIG. 2, an OLED 100 includes a substrate 110, a cathode 120, an organic thin film 130, and an anode 140. To be specific, the OLED 100 has a stacked structure where the cathode 120, the organic thin film 130 and the anode 140 are formed on the substrate 110 in sequence.

A glass substrate is used for the substrate 110, and a plastic substrate may also be used in case of realizing a flexible display.

The cathode 120 is formed on the substrate 110 using a metal paste through an atmospheric pressure coating method. The metal paste may include silver (Ag), aluminum (Al), silver-magnesium (Ag—Mg) alloy, or the like.

The organic thin film 130 is formed on the cathode 120. The organic thin film 130 serves as an organic emission layer to be described later.

The anode 140 is formed on the organic thin film 130 using a transparent conductive material such as indium tin oxide (ITO), indium zinc oxide (IZO), and Al-doped zinc oxide (AZO).

As described above, when the cathode 120 is formed using the metal paste, it is possible to form the cathode without an additional process of forming a pattern.

An OLED of the exemplary embodiment of FIG. 3 is similar in structure to the OLED of the foregoing exemplary embodiment of FIG. 2 except for an organic thin film, and thus following description will be mainly focused on the organic thin film.

Referring to FIG. 3, the OLED 100 includes a cathode 120 on a substrate 100, an organic thin film 130 on the cathode 120, and an anode 140 on the organic thin film 130.

The organic thin film 130 includes an electron injection layer (EIL) 131, an electron transport layer (ETL) 133, an organic emission layer (EMIL) 135, and a hole transport layer (HTL) 137, and a hole injection layer (HIL) 139.

In the organic thin film 130, the electron injection layer 131, the electron transport layer 133, the organic emission layer 133, the hole transport layer 137 and the hole injection layer 139 are sequentially stacked over the cathode 120. The organic thin film 130 may be formed using a deposition or coating process.

Although this exemplary embodiment illustrates that the electron injection layer 131, the electron transport layer 133, the organic emission layer 135, the hole transport layer 137 and the hole injection layer 139 are sequentially formed in the organic thin film 130, the present invention is not limited thereto but the organic thin film 130 may be variously formed.

For example, the organic thin film may have various stacked structures such as electron injection layer/organic emission layer, organic emission layer/hole injection layer, electron injection layer/organic emission layer/hole injection layer, electron transport layer/organic emission layer/hole injection layer, electron injection layer/electron transport layer/organic emission layer/hole injection layer, electron injection layer/electron transport layer/organic emission layer/hole transport layer/hole injection layer and so forth.

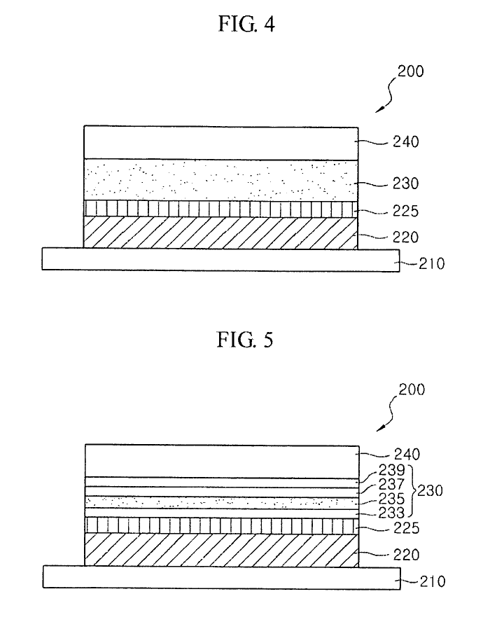

FIG. 4 is a schematic sectional view of an OLED in accordance with still another exemplary embodiment, and FIG. 5 is a schematic sectional view of an OLED in accordance with yet another exemplary embodiment.

Referring to FIG. 4, an OLED 200 includes a substrate 210, a cathode 220, an inorganic thin film 225, an organic thin film 230, and an anode 240. To be specific, the OLED 200 has a stacked structure where the cathode 220, the inorganic thin film 225, the organic thin film 230 and the anode 240 are formed on the substrate 210 in sequence.

A glass substrate is used for the substrate 210, and a plastic substrate may also be used in case of realizing a flexible display.

The cathode 220 is formed on the substrate 210 using a metal paste through an atmospheric pressure coating method. The metal paste may include silver (Ag), aluminum (Al), silver-magnesium (Ag—Mg) alloy, or the like.

The inorganic thin film 225 is formed on the cathode 220. The inorganic thin film 225 may include titanium oxide (TiOₓ) or zinc oxide (ZnOₓ), or may include an N-type inorganic thin film formed by adding N-type impurities such as silicon (Si), germanium (Ge), tin (Sn), tellurium (Te) or sulfur (S) into an inorganic compound.

The organic thin film 230 is formed on the inorganic thin film 225. The organic thin film 230 serves as an organic emission layer.

The anode 240 is formed on the organic thin film 230 using a transparent conductive material such as indium tin oxide (ITO), indium zinc oxide (IZO), Al-doped zinc oxide (AZO) and so forth.

An OLED of the exemplary embodiment of FIG. 5 is similar in structure to the OLED of the aforesaid exemplary embodiment of FIG. 4 except for an organic thin film, and thus following description will be mainly focused on the organic thin film.

Referring to FIG. 5, the organic thin film 230 includes an electron transport layer 233, an organic emission layer 235, a hole transport layer 237, and a hole injection layer 239, which are stacked in sequence. The organic thin film 230 may be formed using deposition or coating process.

Although this exemplary embodiment illustrates that the electron transport layer 233, the organic emission layer 235, the hole transport layer 237 and the hole injection layer 239 are sequentially formed in the organic thin film 230, the present invention is not limited thereto but the organic thin film 230 may he variously formed.

For example, the organic thin film may have various stacked structures such as electron injection layer/organic emission layer, organic emission layer/hole injection layer, electron injection layer/organic emission layer/hole injection layer, electron transport layer/organic emission layer/hole injection layer, electron injection layer/electron transport layer/organic emission layer/hole injection layer, and electron injection layer/electron transport layer/organic emission layer/hole transport layer/hole injection layer.

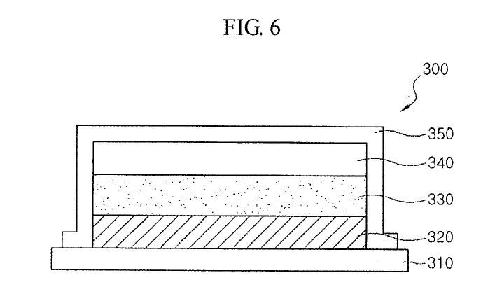

FIG. 6 is a schematic sectional view of an OLED in accordance with further exemplary embodiment.

Referring to FIG. 6, an OLED 300 includes a substrate 310, a cathode 320, an organic thin film 330, an anode 340, and an encapsulation layer 350. To be specific, the OLED 300 has a stacked structure where the cathode 320, the organic thin film 330, the anode 340, and the encapsulation layer 350 are formed on the substrate 310 in sequence.

The encapsulation layer 350 may be formed of glass or thin film that allows light emitted upward through the anode 340 to be transmitted.

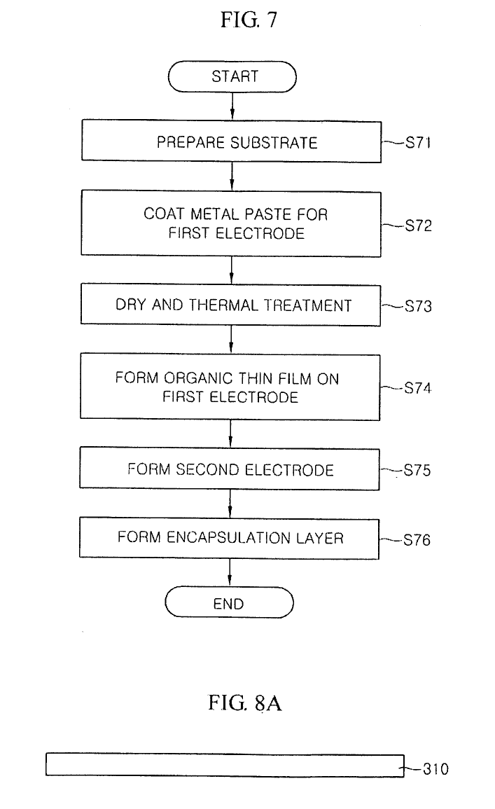

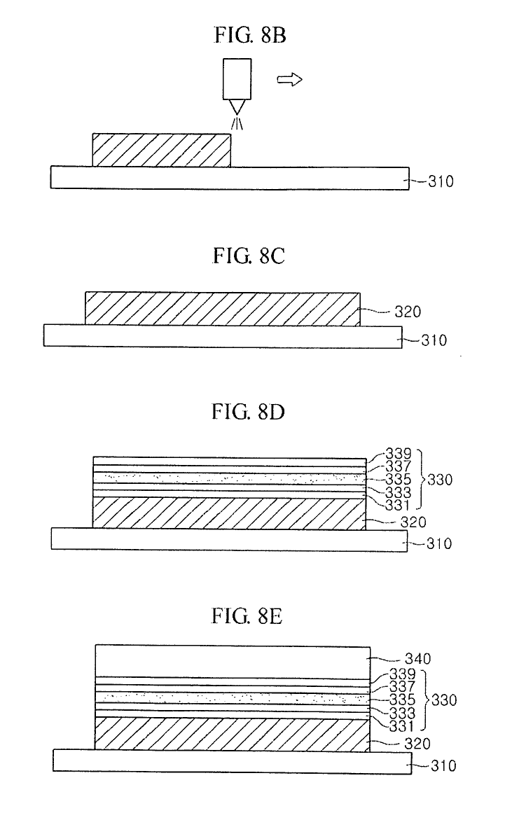

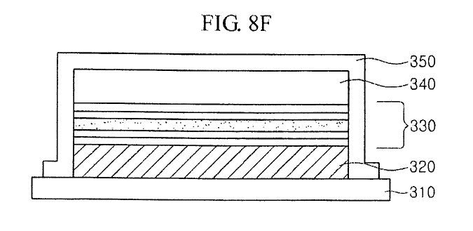

FIG. 7 is a flowchart illustrating a method for manufacturing an OLED in accordance with an exemplary embodiment, and FIGS. 8A through 8F are sectional views illustrating the method for manufacturing the OLED in FIG. 7.

Referring to FIG. 7, in operation S71, the method for manufacturing the OLED begins with preparing a substrate first. At this time, a glass substrate is used for the substrate, and a plastic substrate may also be used in case of realizing a flexible display.

In operation S72, a process of coating a metal pate for a first electrode is performed so as to form a first electrode, i.e., cathode, on the substrate. The metal paste may include silver (Ag), aluminum (Al) or silver-magnesium (Ag—Mg) alloy, but is not limited thereto. For example, the metal plate may be formed of various metals with high reflectivity.

In operation S73, a drying process and a thermal treatment are performed on the metal paste to form the first electrode. The thermal treatment is performed at a temperature ranging from approximately 100° C. to approximately 500° C.

Thereafter, in operation S74, an organic thin film is formed on the first electrode. The organic thin film may include only an organic emission layer, or a multilayer where an electron injection layer, an electron transport layer, a hole transport layer or a hole injection layer is formed in addition to the organic emission layer.

In operation S75, a second electrodes i.e., anode is formed on the organic thin film. The anode is formed of a transparent conductive material such as indium tin oxide (ITO), indium zinc oxide (IZO), Al-doped zinc oxide (AZO) and so forth.

Afterwards, in operation S76, a process of forming an encapsulation layer is performed.

FIGS. 8A through 8F are sectional views illustrating the method for manufacturing the OLED in FIG. 7.

In the method for manufacturing the OLED with reference to FIGS. 8A through 8F, a substrate 310 formed of glass or plastic is prepared first as illustrated in FIG. 8A.

Referring to FIGS. 8B and 8C, the substrate 310 is coated with a metal paste so as to form a cathode 320, and the metal paste is then dried and thermally treated. In this exemplary embodiment, the coating process is performed using an inkjet printing method, but is not limited thereto. For example, the coating process nay be formed using a screen printing method, a gravier printing method, or a spin coating method.

Referring to FIG. 8D, an electron injection layer 331, an electron transport layer 333, an organic emission layer 335, a hole transport layer 337 and a hole injection layer 339, which form an organic thin film 330, are sequentially formed on the cathode 320.

Next, referring to FIGS. 8E and 8F, an anode 340 is formed on the organic thin film 330, and an encapsulation layer 350 is then formed on the resultant structure.

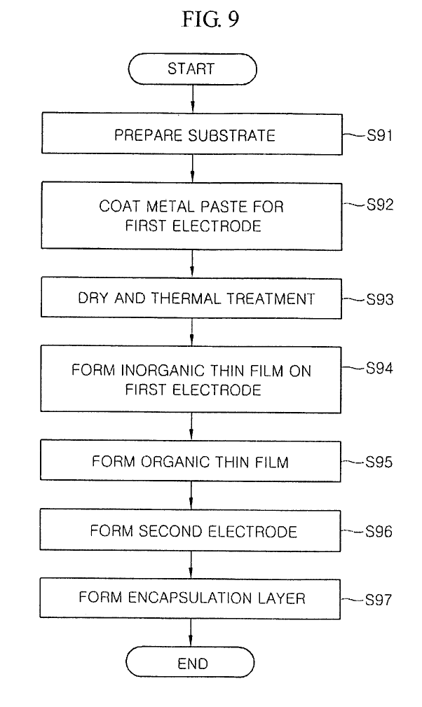

FIG. 9 is a flowchart illustrating a method for manufacturing an OLED in accordance with another exemplary embodiment. A method for manufacturing an OLED in accordance with this exemplary embodiment of FIG. 9 is similar to the manufacturing method in accordance with the foregoing exemplary embodiment of FIG. 7 except that an inorganic thin film is further formed, and thus following description will be mainly made on the formation of the inorganic thin film.

Referring to FIG. 9, in operation S91, a substrate is prepared first.

In operation S92, a process of coating a metal pate for a first electrode is performed so as to form a first electrode, i.e., cathode, on the substrate. The metal paste may include silver (Ag), aluminum (Al) or silver-magnesium (Ag—Mg) alloy, but is not limited thereto. For example, the metal plate may be formed of various metals with high reflectivity.

In operation S93, a drying process and a thermal treatment are performed on the metal paste to form the first electrode.

Thereafter, in operation S94, an inorganic thin film is formed on the first electrode. Herein, the inorganic thin film may include an N-type inorganic thin film formed by adding N-type impurities such as silicon (Si), germanium (Ge), tin (Sn), tellurium (Te) or sulfur (S) into an inorganic compound.

In operation S95, an organic thin film is formed on the inorganic thin film.

In operation S96, a second electrode, i.e., anode is formed on the organic thin film. The anode is formed of a transparent conductive material such as indium tin oxide (ITO), indium zinc oxide (IZO), Al-doped zinc oxide (AZO) and so forth. Afterwards, in operation S97, a process of forming an encapsulation layer is performed.

In accordance with the present invention, when a metal electrode is formed using a metal paste, a manufacturing process is simplified because it is unnecessary to perform an additional patterning process, and the manufacturing, process is environment-friendly because the discharge amount of contaminants is reduced, thus making it possible to reduce manufacturing cost.

In addition, when a metal electrode is formed using a metal paste, a thermal treatment can be performed at a temperature up to an available temperature for a substrate, which can provide the effect of improvement in layer quality and material selection.

Although the OLED and the method for manufacturing the same have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A method for manufacturing an organic light emitting diode (OLED), the method comprising:
forming a first electrode on a substrate using a metal paste;
forming an organic thin film on the first electrode; and
depositing a second electrode on the organic thin film, the second electrode comprising a transparent conductive oxide.

2. The method of claim 1, wherein the forming of the first electrode comprises:
coating the substrate with a metal paste;
drying the metal paste; and
performing a heat-treatment of the metal paste.

3. The method of claim 1, wherein the organic thin film comprises an organic emission layer.

4. The method of claim 1, further comprising depositing an inorganic thin film on the first electrode after the forming of the first electrode on the substrate,
wherein the inorganic thin film is an N-type inorganic thin film formed by adding an N-type impurity into an inorganic compound.

5. The method of claim 1, further comprising forming an encapsulation layer.

6. The method of claim 1, wherein the metal paste comprises one of silver (Ag), aluminum (Al) and silver-magnesium (Ag—Mg) alloy.

7. The method of claim 2, wherein the performing of the heat-treatment of the metal paste comprises performing the heat-treatment at a temperature ranging from approximately 100° C. to approximately 500° C.

8. The method of claim 2, wherein the coating of the substrate with the metal paste comprises coating the substrate with the metal paste under atmospheric pressure using one of a screen printing method, a spin-coating method, a gravier printing method, and an inkjet printing method.

9. The method of claim 3, wherein the organic thin film further comprises one of an electron injection layer, an electron transport layer, a hole transport layer, a hole injection layer, and combinations thereof.

10. An OLED comprising:
a first electrode disposed on a substrate;
an organic thin film disposed on the first electrode; and
a second electrode disposed on the organic thin film, and formed of a transparent conductive oxide,
wherein the first electrode is formed using a metal paste.

11. The OLED of claim 10, wherein the organic thin film comprises an organic emission layer.

12. The OLED of claim 10, further comprising an inorganic thin film disposed between the first electrode and the organic thin film,
wherein the inorganic thin film is an N-type inorganic thin film formed by adding an N-type impurity into an inorganic compound.

13. The OLED of claim 10, further comprising an encapsulation layer provided on the second electrode.

14. The OLED of claim 10, wherein the metal paste comprises one of silver (Ag) aluminum (Al) and silver-magnesium (Ag—Mg) alloy.

15. The OLED of claim 10, wherein the transparent conductive oxide comprises one of indium tin oxide (ITO), indium zinc oxide (IZO), and Al-doped zinc oxide (AZO).

16. The OLED of claim 11, wherein the organic thin film further comprises one of an electron injection layer, an electron transport layer, a hole transport layer, a hole injection layer, and combinations thereof.
